(19) United States
(12) Patent Application Publication
(10) Pub. No.: US 2007/0063347 A1
(43) Pub. Date: Mar. 22, 2007

(54) Packages, anisotropic conductive films, and conductive particles utilized therein

(75) Inventor: Chao-Yuan Su, Kaohsiung (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/229,931

(22) Filed: Sep. 19, 2005

(51) Int. Cl. H01L 23/48

(52) U.S. Cl. 257/741

(57) ABSTRACT

Packages, anisotropic conductive films, and conductive particles utilized therein. One embodiment of the package includes a substrate, a chip, and an anisotropic conductive film. The substrate comprises an external terminal. The chip comprises a conductive bump overlying the external terminal of the substrate. The anisotropic conductive film is disposed between the substrate and the chip and comprises an adhesive binder and conductive particles distributed therein. Conductive particles comprise a conductive core surrounded by an insulating shell. At least one of the conductive particles is disposed between the conductive bump and the external terminal, and the insulating shell thereof fractures to expose the conductive core thereof, electrically connecting the conductive bump and the external terminal.

### BACKGROUND

The invention relates to semiconductor technology, and more specifically to a flip chip assembly.

The attachment of a bare chip to a wiring substrate (either flip chip or chip on board; COB) or a glass panel (chip on glass; COG) is an advanced application electrically connecting integrated circuits (ICs) achieving the lighter weight, smaller size, and lower cost and power consumption demanded by various electronic products.

Anisotropic conductive film (ACF) is more and more popularly utilized to attach chips to the described substrate rather than underfill, due to fine pitch capability, low temperature process capability, flux-less processing and product, flexible and simple processing to achieve low cost capability, high throughput, and lead free solution. ACF is an adhesive film consisting of conductive particles in an insulating adhesive film about 15 to 35 μm thick. The following conventional method is used to fabricate a flip chip assembly utilizing the ACF.

As shown in FIG. 1A, a substrate 22 comprises a bonding pad 21 thereon. An ACF 10 is laminated on the substrate 22 at approximately 100° C. The ACF comprises nickel particles 19 between 3 and 5 microns in diameter in an adhesive binder 20. A chip 1 comprises bumps 3 electrically connecting to interior wiring thereof and a passivation layer 2 on a surface, isolating the bumps 3 from each other. The bumps 3 of chip 1 are aligned with the corresponding pads 21 of the substrate 22, followed by application of pressure P and/or heat to the chip 1, attaching the chip 1 to the substrate 22 at approximately 100° C.

As shown in FIG. 1B, the applied pressure and/or heat transferred to the bumps 3 drives the binder 20 to flow, resulting in disposition of at least one nickel particle 19 between every bump 3 and corresponding pad 21, generating electrical connection therebetween. In some cases, flow of the binder 20 further drives some nickel particles 19 to gather in the space between the bumps 3 and/or pads 21, again, generating electrical connection therebetween. This, undesirable electrical shorting between the adjacent bumps 3 and/or pads 21, negatively affects process yield. Occurrence of the described short or bridge problems sharply increases with decrease in pitch of the bumps 3.

Further, the ACF 10 is heated to approximately 100° C. during the described process, resulting in potential oxidization of the nickel particles 19. High impedance or open between the bumps 3 and the corresponding pads 21 occurs when the nickel particles 19 therebetween are oxidized, negatively affecting process yield and product reliability.

Kim et al. disclose a method of coating an insulating film on sidewalls of the bumps 3 to prevent electrical short therebetween in U.S. Pat. No. 6,232,563. Kim et al., however, do not prevent electrical shorts between the pads 21 as shown in FIG. 1B and oxidization of the nickel particles 19. Solutions for the described problems are still desired.

### SUMMARY

Thus, embodiments of the invention provide packages, methods for fabricating the same, anisotropic conductive films, and conductive particles utilized therein, preventing the described short and oxidation problems, thereby improving process yield product reliability.

Embodiments of the invention provide a conductive particle utilized in an anisotropic conductive film. The particle comprises a conductive core surrounded by an insulating shell. The insulating shell fractures but the conductive core does not fracture under the same predetermined stress.

Embodiments of the invention further provide an anisotropic conductive film. The film comprises an adhesive binder and conductive particles distributed therein. Every conductive particle comprises a conductive core surrounded by an insulating shell. The insulating shell fractures but the conductive core does not fracture under the same predetermined stress.

Embodiments of the invention further provide a package. The package comprises a substrate, a chip, and the anisotropic conductive film. The substrate comprises an external terminal thereon. The chip comprises a conductive bump overlying the external terminal of the substrate. The anisotropic conductive film is disposed between the substrate and the chip. The anisotropic conductive film comprises an adhesive binder and conductive particles distributed therein. Every conductive particle comprises a conductive core surrounded by an insulating shell. At least one of the conductive particles is disposed between the conductive bump and the external terminal, and the insulating shell thereof fractures to expose the conductive core thereof, electrically connecting the conductive bump and the external terminal.

Embodiments of the invention further provide a method for fabricating a package. First, a substrate comprising an external terminal is provided. Next, an anisotropic conductive film is attached to the substrate overlying the external terminal. Finally, a chip comprising a conductive bump is attached to the substrate under pressure, disposing at least one conductive particle between the conductive bump and the external terminal. The insulating shell of the conductive particle fractures under stress from the pressure to expose the conductive core thereof, electrically connecting the conductive bump and the external terminal.

Further scope of the applicability of the invention will become apparent from the detailed description given hereinafter. It should be understood, however, that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention can be more fully understood by reading the subsequent detailed description in conjunction with the examples and references made to the accompanying drawings, which are given by way of illustration only, and thus are not limitative of the invention, and wherein:

FIGS. 1A and 1B are cross-sections of a conventional method for fabricating a package.

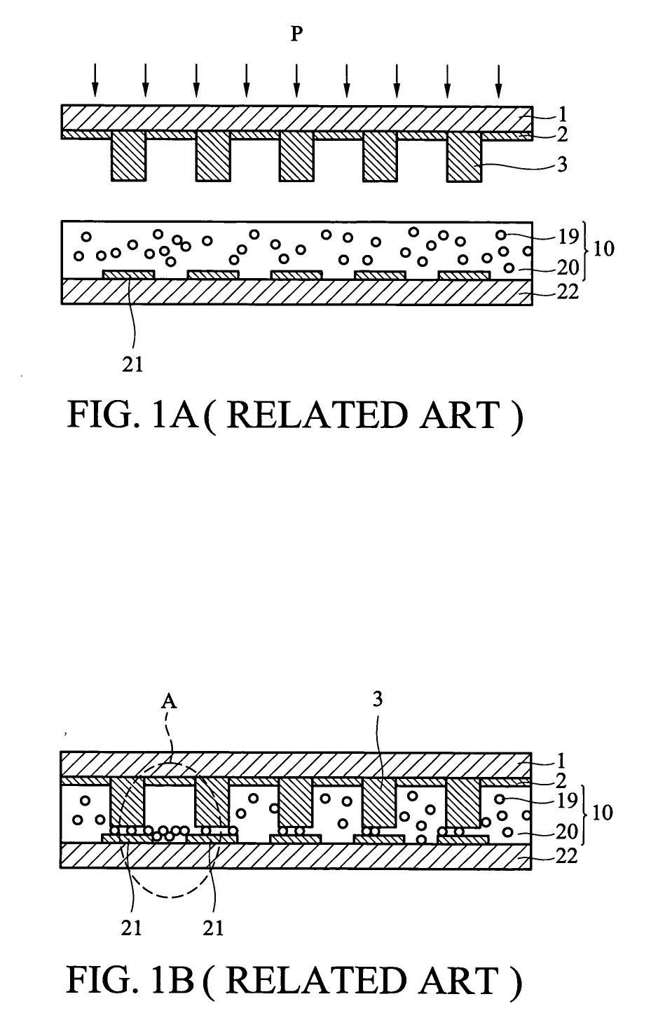

FIGS. 2A through 2C are cross-sections of packages, methods for fabricating the same, anisotropic conductive films r, and conductive particles utilized therein of one embodiment of the invention.

FIG. 3 is a cross-section of reworked packages of the invention.

### DESCRIPTION

The following embodiments are intended to illustrate the invention more fully without limiting the scope of the claims, since numerous modifications and variations will be apparent to those skilled in this art.

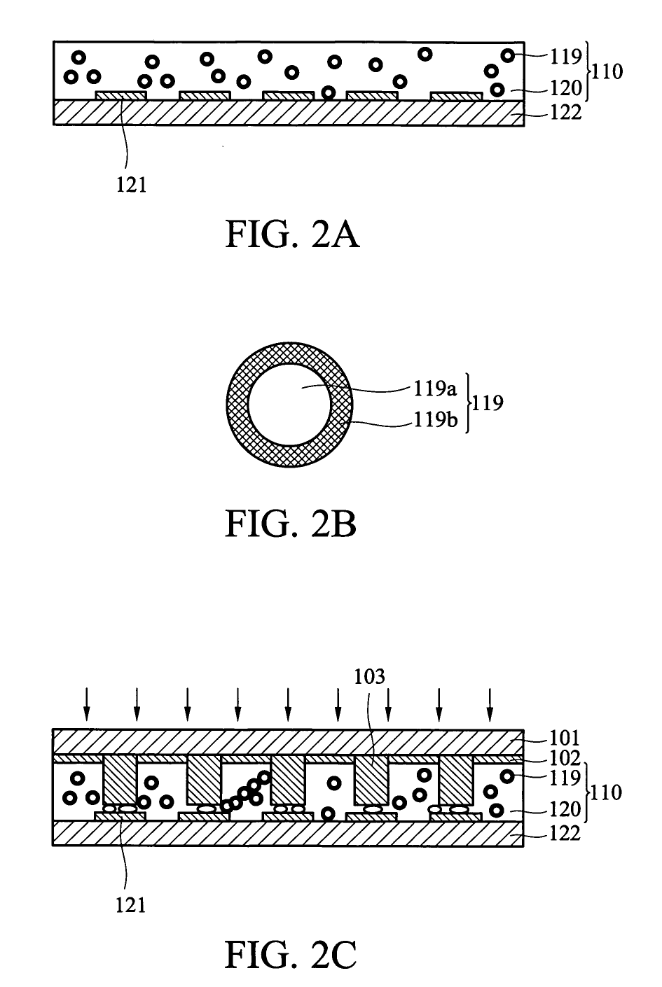

FIG. 2A shows an anisotropic conductive film (ACF) 110 attached to or laminated on a substrate 122 comprising a bonding pad 121 thereon. FIG. 2B shows a conductive particle 119 utilized in the ACF 110.

As shown in FIG. 2B, the particle 119 comprises a conductive core 119a and an insulating shell 119b surrounding the conductive core 119a. The insulating shell 119b fractures to exposed the conductive core 119a under a predetermined stress exerted in a subsequent die attachment procedure. When the ACF 10 is utilized in a flip chip package or the like, for example, the particle 119 is preferably as large as approximately 5 to approximately 20 microns in diameter. In some embodiments, the conductive core 119a is lead free. In some embodiments, the conductive core 119a comprises metal, such as nickel, solder, silver, gold, or copper. In one embodiment, the conductive core 119a comprises nickel. In some embodiments, the insulating shell 119b comprises silica or polymer such as polyimide.

As shown in FIG. 2A, the ACF 110 comprises an adhesive binder 120 and the conductive particles 119 distributed therein. Conductive particles 119 comprise a conductive core 119a surrounded by an insulating shell 119b. In some embodiments, the binder 120 is thermoplastic. In some alternative embodiments, the binder 120 is thermosetting.

In FIG. 2A, the substrate 122 can be organic, ceramic, metallic, or other substrate with wiring for flip chip package or chip-on-board package. Alternatively, the substrate 122 can be an LCD substrate for an LCD. In some embodiments, the ACF 110 is preferably attached to or laminated on the substrate 122 at approximately 100° C., and the insulating shell 119b protects the conductive core 119a therein from oxidation for every conductive particle 119, preventing the conventional high impedance or open problems.

In FIG. 2C, a chip 1, comprising bumps 3 thereon, is provided. The bumps 3 electrically connect to interior wiring of the chip 1. Further, a passivation layer 2 is disposed on the chip 1, isolating the bumps 3 from each other. The bumps 3 of the chip 1 align with the corresponding pads 121 of the substrate 122, followed by application of pressure P and/or heat to chip 1, attaching the chip 1 to the substrate 122. In some embodiments, the attachment temperature is approximately 100° C. In some embodiments, the pressure P is between 500 and 5000 g/mm². During attachment, the applied pressure and/or heat transferred to the bumps 3 drives the binder 120 to flow, resulting in disposition of at least one conductive particle 119 between the bumps 3 and corresponding pads 121. Simultaneously, stress induced by the pressure P fractures the insulating shells 119b of every conductive particle 119 between every bump 3 and the corresponding pad 121 to expose the conductive cores 119a therein, electrically connecting the bumps 3 and corresponding pads 121. Simultaneously, in every other conductive particle 119, the insulating shell 119b remains intact surrounding the conductive core 119a. In some embodiments, a ratio of core diameter and shell thickness in a conductive particle 119 is between 1% and 10%.

In some cases, flow of the binder 120 further drives some conductive particles 119 to gather in the space between the bumps 3 and/or in the space between pads 121 as shown in FIG. 2C. These linked bumps 3 or pads 121 by the particles 119, however, are not electrically connected due to the insulating shells 119b of the linking particles 119. Thus, bridging problems are prevented, improving process yield and product reliability.

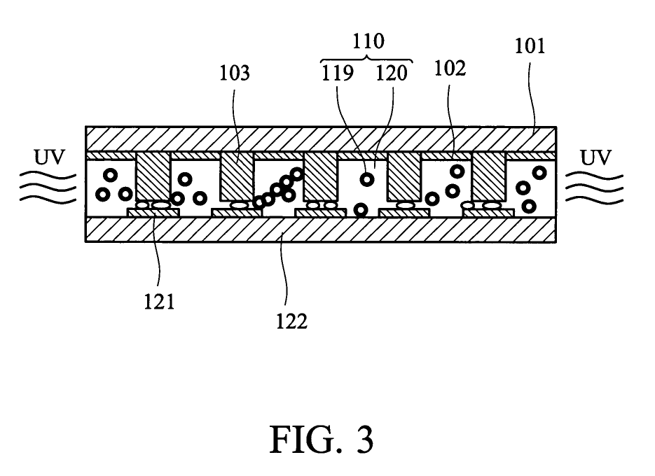

In some embodiments, adhesion of the binder 120 decays when illuminated by UV for reworking a packaged device, in which case the binder 120 is preferably UV sensitive. When the package is to be reworked, the package is illuminated by UV at a predetermined intensity and time as shown in FIG. 3. Thus, the chip 101, the ACF 110, and the substrate 122 can be separated from each other, followed by repeat steps as described in FIGS. 2A and 2C to complete reworking.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. A conductive particle utilized in an anisotropic conductive film, comprising:
a conductive core; and
an insulating shell surrounding the conductive core, wherein the insulating shell fractures to expose the conductive core under a predetermined stress.

2. The particle as claimed in claim 1, wherein a ratio of core diameter and shell thickness is between 1% and 10%.

3. The particle as claimed in claim 1, wherein diameter of the particle is as large as approximately 5 to approximately 20 microns.

4. The particle as claimed in claim 1, wherein the conductive core is lead free.

5. The particle as claimed in claim 1, wherein the conductive core comprises metal.

6. The particle as claimed in claim 1, wherein the conductive core comprises nickel.

7. The particle as claimed in claim 1, wherein the insulating shell comprises silica or polymer.

8. An anisotropic conductive film, comprising:
an adhesive binder; and
conductive particles in the binder, the conductive particles comprising a conductive core surrounded by an insulating shell, wherein the insulating shell fractures to expose the conductive core under a predetermined stress.

9. The film as claimed in claim 8, wherein a ratio of core diameter and shell thickness is between 1% and 10%.

10. The film as claimed in claim 8, wherein the particles are as large as approximately 5 to approximately 20 microns in diameter.

11. The film as claimed in claim 8, wherein the conductive core is lead free.

12. The film as claimed in claim 8, wherein the conductive core comprises metal.

13. The film as claimed in claim 8, wherein the conductive core comprises nickel.

14. The film as claimed in claim 8, wherein the insulating shell comprises silica or polymer.

15. The film as claimed in claim 8, wherein the binder is thermoplastic or thermosetting.

16. A package, comprising:
a substrate comprising an external terminal thereon;
a chip comprising a conductive bump overlying the external terminal of the substrate; and
an anisotropic conductive film between the substrate and the chip, the anisotropic conductive film comprising an adhesive binder and conductive particles therein, the conductive particles comprising a conductive core surrounded by an insulating shell;
wherein at least one of the conductive particles is disposed between the conductive bump and the external terminal, and the insulating shell thereof fractures to expose the conductive core thereof, electrically connecting the conductive bump and the external terminal.

17. The assembly as claimed in claim 16, wherein a ratio of core diameter and shell thickness is between 1% and 10%.

18. The package in claim 16, wherein the particles are as large as approximately 5 to approximately 20 microns in diameter.

19. The package in claim 16, wherein the conductive core is lead free.

20. The package in claim 16, wherein the conductive core comprises metal.

21. The package in claim 16, wherein the conductive core comprises nickel.

22. The package in claim 16, wherein the insulating shell comprises silica or polymer.

23. The package in claim 16, wherein the binder is thermoplastic or thermosetting.
